(19) United States
(12) Patent Application Publication
(10) Pub. No.: US 2009/0067616 A1
(43) Pub. Date: Mar. 12, 2009

(54) CAN echo cancellation level shifter

(76) Inventor: Kerby William Suhre, Fenton, MI (US)

Correspondence Address: Michael T. Raggio, Ste. 410, 2701 Cambridge Court, Auburn Hills, MI, 48326, US

(21) Appl. No.: 11/899,674

(22) Filed: Sep. 7, 2007

(51) Int. Cl. H03K 3/037; H04M 9/08

(52) U.S. Cl. 379/406.06; 327/225

(57) ABSTRACT

An echo cancellation system for use with a controller area network having at least two physical layers is disclosed. The system includes a flip flop circuit and a first resistor capacitor tank circuit and a second resistor capacitor tank circuit. The echo cancellation system uses a transition dependent delay in the circuit that will be tuned to be longer than the propagation delay of the CAN transceivers but less than the bit sample point for the CAN network thus eliminating any possibility of oscillation occurring within the CAN network during transfer of information between physical layers.

### BACKGROUND OF THE INVENTION

1. Field of the Invention

The present invention relates generally to an echo cancellation circuit for a controller area network (CAN) and more particularly relates to a CAN echo cancellation level shifter for use with a CAN having multiple physical layers.

2. Description of Related Art

A bus system that is suitable for serial data transfer of binary data from one bus system to at least one other bus system has been known for many years. One such prior art bus system is a controller area network (CAN) which are used in motor vehicle electronics and the like. Many of these motor vehicles use electrical components and have more than one local bus system that may for example operate at different data transmission rates or the like.

One prior art controller area network specification was first developed with generally only one physical layer defined by a dual wire high speed network. Over the years the prior art CAN networks have developed into networks which in some cases may have a plurality of physical layers that generally have been defined as a dual wire fault tolerant and a single wire system. The advent of multiple physical layers in CAN networks makes it is necessary to adapt one physical layer to another physical layer in the many interactions within the controller area network. This adoption of one physical layer to another physical layer also may occur when converting a CAN physical layer to a different signal type, such as a RS-485 or fiber type before returning to another CAN physical layer.

Many of these prior art CAN systems are multiple access arbitrated bus systems that have collision detection and acknowledgement features therein. Therefore, connecting the different physical layers of these CAN systems together requires more than a simple electrical level shifter. It should be noted that in many prior art CAN networks everything that is transmitted to the physical layer is also received or echoed to allow for the arbitration, collision detection and the acknowledgement of such signal. It is not possible to tie two physical layer transceivers of a CAN network together with a simple connection as it may enter into oscillation as soon as an edge of a signal is detected due to the propagation delay between the two transceivers on the physical layers of the CAN network. Many prior art systems solve these problems by buffering the CAN frames from each side of the CAN network using a CAN controller/memory device and retransmitting to the other physical layer of the CAN network after receiving the entire message. Another such method in the prior art to solve this problem is to design a circuit to prevent the echo during transmission between the physical layers. The buffering of the CAN frames is a straight forward method but it is expensive for the manufacturers. The use of a circuit to prevent the echo while transmitting is difficult to practically apply because preventing the echo usually requires that the system is taking away the ability to properly detect a loss of arbitration and acknowledgement when transmitting from one physical layer to another physical layer of the network. One such prior art network uses a simple flip flop style circuit and tries to prevent the echo during the transmission of dominant bits between the physical layers. Some of these prior art cancellation circuits may exhibit a bad side effect of echoing a short pulse spike at the end of a transmission of a dominant bit due to the propagation delay of the transceivers used in conjunction with the physical layers.

Therefore, there is a need in the art for an echo cancellation level shifter that is capable of preventing echo during transmission of dominant bits between physical layers of a CAN network. There also is a need in the art for a tunable echo cancellation circuit for use with a CAN network. There also is a need in the art for an echo cancellation circuit that uses a transition dependent delay in a CAN network. There also is a need in the art for the use of an echo cancellation circuit that will only delay the feedback signal of the flip flop on falling edge transitions, i.e., dominant to recessive transitions or the like. There also is a need in the art for an echo cancellation delay that will be tuned to be longer than the propagation delay of the CAN transceivers used in the CAN network but less than the bit sample point for the CAN network.

### SUMMARY OF THE INVENTION

One object of the present invention may be to provide a novel echo cancellation circuit for use with a CAN network.

Another object of the present invention may be to provide an echo cancellation circuit that is capable of being tuned to provide echo cancellation up to the maximum feedback delay of the transceivers of any known CAN network.

Still another object of the present invention may be to provide an echo cancellation circuit that uses a transition dependent delay between CAN physical layers of a network.

Still another object of the present invention may be to provide a low cost and easy to implement system for creating echo cancellation between physical layers of a CAN network.

To achieve the foregoing objects, the present invention discloses a system and method for echo cancellation for a controller area network having at least two physical layers. The system includes a flip flop echo cancellation circuit used in conjunction with a first resistor capacitor tank circuit and a second resistor capacitor tank circuit to create an echo cancellation delay on the falling edge transition between physical layers of a CAN network that is longer than the propagation delay of the CAN transceivers but less than a bit sample point for the CAN network.

One advantage of the present invention may be to provide an improved and novel echo cancellation circuit for use in a CAN network.

Still another advantage of the present invention may be to provide an echo cancellation circuit for use in a CAN network bit that is capable of being tuned to specific CAN network requirements.

Yet another advantage of the present invention may be to provide an echo cancellation circuit that uses a transition dependent delay that will only delay the feedback signal of the flip flop circuit on falling edge transitions.

Still another advantage of the present invention may be the use of a low cost and easy to program and manufacture echo cancellation circuit for use with a CAN network.

Other objects, features and advantages of the present invention will become apparent and readily appreciated as the same becomes better understood after reading the following description taken in conjunction with the accompanying drawings.

### BRIEF DESCRIPTION OF THE DRAWINGS

FIG. 1 is a schematic block diagram of an echo cancellation circuit according to the present invention.

FIG. 2 is a state diagram/flow chart of the echo cancellation system and methodology according to the present invention.

### DESCRIPTION OF THE PREFERRED EMBODIMENT(S)

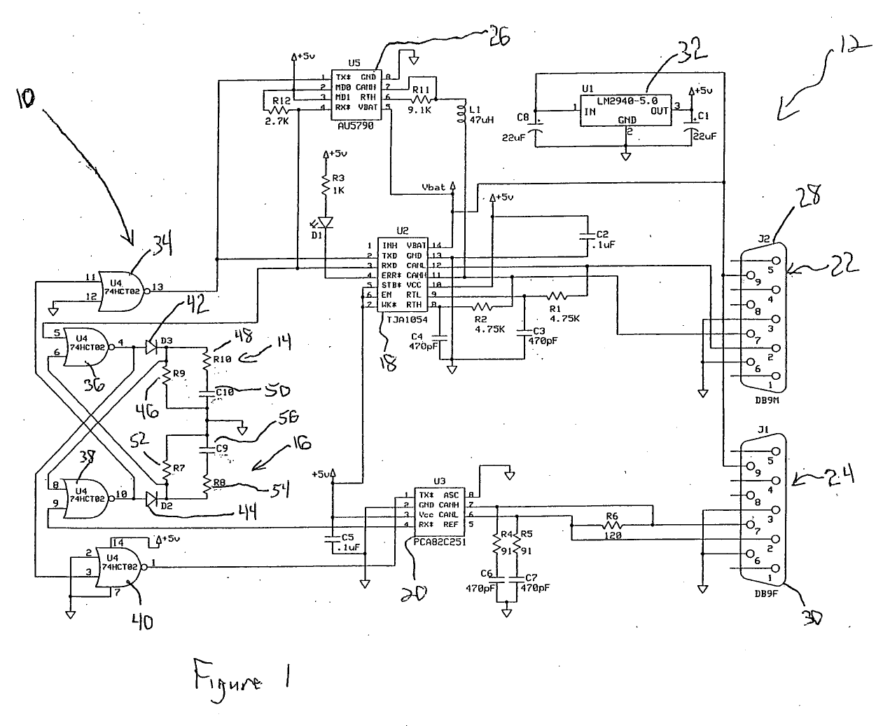

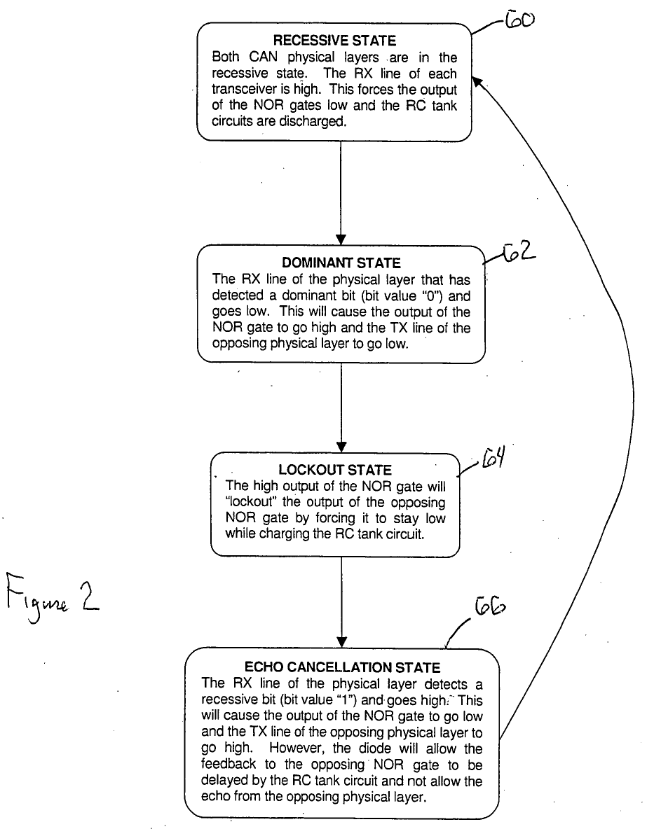

Referring now to FIGS. 1 and 2, an echo cancellation circuit or echo cancellation level shifter 10 according to the present invention is shown. The echo cancellation level shifter 10 is for use in a CAN network 12 having at least two physical layers connected thereto. It should be noted that the CAN network 12 described in the present invention, is generally for use in automotive vehicles, however the present invention of an echo cancellation circuit 10 can be used between any two bus systems that are suitable for serial data transfer of binary data from one of the bus systems to at least one of the other bus systems. Therefore, the present echo cancellation circuit 10 may be used in any sort of CAN network 12 or bus system having at least two buses in any known industry such as automobiles, trains, aviation, space travel, maritime travel, or any other system that uses a controller area network between physical layers of a network system. The present invention takes advantage of the known protocols for how a CAN arbitration and acknowledgement algorithm operates. Such an algorithm like any AC serial protocol, has a bit sampling algorithm that determines whether a bit represents a one “1”, which is deemed a passive bit or zero “0” which is deemed a dominate bit. In the case of a controller area network 12 a programmer has some design choices on setting the number of samples per bit and the sample that will determine the bit value, i.e., or sample point. In most CAN network 12 implementations the sample point is set at approximately 75 to 80% of the total bit time, however any other set point may be used for the total bit time. Therefore, the present invention using the fact that the sample point is known and set at a predetermined percentage of the total bit time allows for the present invention to create a tuned echo cancellation circuit 10 that may prevent echo from occurring within the propagation delay time of the two transceivers connected to different physical layers of a CAN network 12 and therefore avoid any oscillation from occurring such as that found in some prior art CAN network systems.

Many prior art style echo cancellation circuits would attempt to prevent the echo during transmission of the dominant bits but some of them exhibited the side effect of echoing a short pulse spike at the end of the transmission of a dominate bit due to the propagation delay of the transceiver used between the physical layers of the CAN network.

Therefore, the present system and methodology 10 uses an echo cancellation circuit 10 that has a transition dependent delay in the flip flop echo cancellation circuit 10. This transition dependent delay in the echo cancellation circuit 10 of the present invention will only delay the feedback signal of the flip flop circuit 10 on the falling edges that occur during the transitions between the physical layers. These transitions or falling edges generally occur when a dominant to recessive transition, i.e., from zero “0” to one “1” bit representation occurs within the network. It should be noted that the flip flop echo cancellation circuit 10 may also be designed to create an echo delay at any other known transition by any other known points in the transmission of data across the network between physical layers. It should be noted that the echo delay on the falling edges may be determined by two resistor capacitor tank circuits 14, 16 that are part of the echo cancellation circuit 10 wherein those RC tank circuits 14, 16 are tuned to have a delay longer than the propagation delay of the CAN network transceivers 18, 20 but less than the bit sample point for the CAN network 12. It should be noted that the echo cancellation circuit 10 of the present invention is capable of being tuned to provide echo cancellation to any maximum feedback delay of any known transceivers for use within a CAN network 12.

As shown in FIG. 1, the CAN network 12 may have at least two physical layers 22, 24 but may have more physical layers than that is shown in FIG. 1. The CAN network 12 may include a plurality of transceivers 18, 20 wherein each transceiver is connected to a connector 28, which is connected to a physical layer 22, 24 of the CAN network 12. The CAN network 12 also may include a voltage regulator 32 and may even include an optional transceiver 26, such as a single wire interface as shown in FIG. 1. It should be noted that other physical layers may be used in the CAN network 12 other than those shown in FIG. 1, which is just one contemplated embodiment for use with the echo cancellation circuit 10 of the present invention. It should be known that any known type of transceiver may be used with the echo cancellation circuit 10 of the present invention. The transceivers 18, 20 as shown in FIG. 1 are for one contemplated embodiment but any other known transceiver may be substituted and used in conjunction with any known CAN network 12 and with the echo cancellation circuit 10 as described in the present invention.

The echo cancellation circuit 10 generally is a flip flop circuit that uses a plurality of NOR gates to create the flip flop circuit. In one contemplated embodiment as shown a quad two input NOR gate is used to create the flip flop circuit portion of the echo cancellation circuit 10. The quad NOR gate generally includes four NOR gates arranged on an integrated circuit (IC) chip. Each of the NOR gates has two input lines and one output line. The first NOR gate 34 generally has an output line connected to a transmit data input line of the transceiver 18 associated with the first physical layer 22 of the CAN network 12. One of the input lines of the first NOR gate 34 is connected to ground while the other input line of the first NOR gate 34 is connected to the output line of the third NOR gate 38. The second NOR gate 36 has its output line connected to one of the input lines of the third NOR gate 38 and to a first diode 42 of the echo cancellation circuit 10. One of the input lines of the second NOR gate 36 is connected to the received data output line of the transceiver 18 associated with the first physical layer 22 of the CAN network 12. The other input line of the second NOR gate 36 is connected to and in communication with a second RC tank circuit 16 of the echo cancellation circuit 10. The third NOR gate 38 has its output line connected to one of the inputs of the second NOR gate 36 and a second diode 44. The third NOR gate 38 also has one of its input lines connected to the first RC tank circuit 14 of the echo cancellation circuit 10. The other input line of the third NOR gate 38 is connected to the receiver data output line of the transceiver 20 associated with the second physical layer 24 of the CAN network 12. The fourth NOR gate 40 has its output line connected to the transmit data input line of the transceiver 20 associated with the second physical layer 24 of the CAN network 12. One of the input lines of the fourth NOR gate 40 is connected to the output line of the second NOR gate 36 while the other input line is connected to ground. This flip flop circuit will when the output of one of either the second or third NOR gate 36, 38 goes high to lock out the output of the opposing NOR gate or force it to stay low while charging of the associated RC tank circuit occurs. Therefore, the flip flop design will allow for the appropriate echo delay to occur thus allowing for transmission of the information without echo occurring within the propagation delay time of the two transceivers 18, 20 therefore avoiding any oscillation possibility.

The echo cancellation circuit 10 also includes a first and second resistor capacitor (RC) tank circuit 14, 16 as shown in FIG. 1. The first RC tank circuit 14 includes a first resistor 46 and a second resistor 48 and a first capacitor 50. The second RC tank circuit 16 includes a third resistor 52 and a fourth resistor 54 and a second capacitor 56. The first RC tank circuit 14 is connected to the first diode 42 on one end thereof and to ground on the other end thereof. The second RC tank circuit 16 is connected to the second diode 44 on one end thereof and to ground on the second end thereof. The first RC tank circuit 14 has an output connected to an input line of the third NOR gate 38 while the second RC tank circuit 16 has its output connected to an input line of the second NOR gate 36. This will allow for the echo delay to be tuned to be longer than the propagation delay of the CAN transceivers 18, 20 but less than the bit sample point for the CAN network 12. It should be noted that in one contemplated embodiment the first and third resistors 46, 52 for the tank circuits will be 9.1 K ohm resistors while the third and fourth resistors 48, 54 of the first and second tank circuits respectively will be 390 ohm resistors. It should be noted that the capacitors for the first and second tank circuits 14, 16 may have a rating of 470 or 220 pico farad (pF) or any other known value. These values may be different from those shown thus making the echo cancellation circuit tunable to specific CAN networks and transceivers associated with the physical layers of the CAN networks on which the echo cancellation will be used. The first and second diodes 42, 44 may allow the feedback signal to the opposing NOR gate to be delayed by the RC tank circuit and not allow an echo from the opposing physical layer to interfere and thus create an oscillation therein.

In operation, the echo cancellation circuit 10 is tuned to provide echo cancellation up to a maximum feedback delay of the transceivers 18, 20 used in the circuit 10 while not exceeding the bit sample point of the CAN network 12. Generally, the maximum feedback of a transceiver is approximately 250 nanoseconds in a worse case scenario. However, it should be noted that transceivers may have maximum feedback delays of anywhere from ten nanoseconds to many thousands of nanoseconds. The circuit 10 also must determine what the maximum bit rate of the highest speed CAN network is for either a dual wire high speed network, single wire high speed network or the like. In the one contemplated embodiment one mega bite per second is the maximum bit rate of the high speed CAN network 12 presently known, which makes the minimum bit time approximately one microsecond. Generally, the echo cancellation circuit tuning uses a typical bit sample point of 75 to 80% of the maximum bit rate which in the example provided herein gives maximum echo cancellation that must be less than 750 nanoseconds. The tuning also must allow for the propagation delay in the CAN bus wires and topology such that in designing the circuit 10 the designer would not want to exceed 400 nanoseconds or approximately 40% of the bit time of the maximum bit rate of the high speed CAN network 12. However, it should be noted that any other percentage of bit time may also be used according to the present invention depending on the design requirements of the network in which the echo cancellation circuit 10 will be used. The NOR gates used in the present invention, as shown in FIG. 1, are composed of high speed CMOS technology HCT parts and have an approximate switching voltage that is one half of the supply voltage. Therefore, the NOR gates used in the present invention need an RC tank circuit that will discharge one half of the supply voltage in approximately 40% of the bit time or in our example shown 400 nanoseconds. Based on the examples described above for our schematic in FIG. 1, the RC time constant would be 220 PF times 390 ohms which would equal approximately 680 nanoseconds. The designer of the echo cancellation circuit 10 would then use an RC discharge equation which in our contemplated circuit 10 as shown in the present invention is VO equals VI times E to the (T over 680 nanoseconds) times 2700 divided by 390. Wherein this RC discharge equation VO equals the output voltage of the RC tank circuit to the opposing NOR gate, VI is the initial charge voltage of the capacitor in the RC tank circuit and T is the discharge time of the RC tank circuit.

Therefore, with the switching voltage at half of the supply the echo cancellation circuit 10 would have a target voltage of approximately VI divided by 2. Using the values of the contemplated embodiment in the schematic shown in FIG. 1, the echo cancellation time would be approximately 381 nanoseconds which would allow the use of a 5% tolerance capacitor in the tank circuit without exceeding the 400 nanosecond limitation which allows for the propagation delay between the CAN bus wires and topology and transceivers 18, 20. The echo cancellation circuit 10 may also need to be charged to very near the full supply voltage within a single bit time without exceeding the output current capability of the NOR gates in the echo cancellation circuit 10. Therefore, one of the resistors 48, 54 in the example shown in the RC tank circuits 14, 16 will limit the current to the capacitor 50, 56 during charging while still guaranteeing that the capacitor will be charged to 99.999% of the supply voltage and the fastest bit time which in our example is approximately one mega bit per second. Therefore, a designer can use the echo cancellation circuit 10 as described above and tune it by adjusting the values of the RC tank circuit resistors and capacitors to allow for an echo delay to ensure that no echo occurs on the falling edge of the CAN network binary systems. Therefore, the present invention provides a tunable echo cancellation circuit that is inexpensive to make and easy to implement into various CAN networks which allows for design variations to be made in a short amount of time by the designer of the CAN network 12. It also will eliminate any echo from occurring thus eliminating the possibility of oscillation and voltage spikes within the CAN network 12 when data is being transferred between physical layers 22, 24 of the CAN network 12.

FIG. 2 shows a state diagram/flow chart of the states in which the methodology and system of the echo cancellation circuit 10 of the present invention will be used. Four states may occur within the echo cancellation circuit 10 of the present invention. These include a recessive state 60, a dominate state 62, a lock out state 64 and an echo cancellation state 66. In the recessive state 60, both of the CAN physical layers 22, 24 will be in a recessive or passive state represented by a one in the binary bit language. The received data output line of each of the transceivers 18, 20 will be high or have a one associated therewith. The received data output lines of the transceivers 18, 20 will force the output lines of the second and third NOR gates 36, 38 to go low, i.e., have a “0” in the bit and the RC tank circuits 14, 16 are discharged.

In the dominate state 62, the received data output line of the transceiver associated with the physical layer that has detected a dominate bit, i.e., when the bit value equals zero, will go low or show a zero. This line becoming low will cause the output of the second or third NOR gate connected to the received data output line to go high or have a one transmitted therefrom which in turn will make the transmit data input line of the opposing transceiver associated with the other physical layer to go low or have a zero represented thereon via the first or fourth NOR gate respectively.

The lockout state 64 for the echo cancellation circuit 10 of the present invention will have a one or high output that has detected a dominate bit will lock out the output of the opposing NOR gate by forcing it to stay low while charging the RC tank circuit associated therewith.

The echo cancellation state 66 of the echo cancellation circuit 10 of the present invention will have the received data output line of the transceiver associated with the physical layer that detects a recessive bit or bit value of one go high. This will cause the output of the associated NOR gate to go low and the transmit data input line of the opposing transceiver associated with the other physical layer to go high or have a bit value of one. However, at the same time the diode associated with that NOR gate will allow the feedback to the opposing NOR gate to be delayed by the RC tank circuit and not allow any echo from the opposing physical layer to occur. This will ensure that no oscillation occurs thus allowing for data to be transmitted across the CAN network in between physical layers without any echo or other errors occurring during transmission of data therebetween. It should be noted that the present invention has been contemplated to be used with automobiles but may be used for any other known CAN network or bus systems and may be sealed to be used in underwater controller area network environments or any other known controller network environments also. It should be noted that any changes to the RC tank circuits and NOR gates may be used depending on the design requirements and CAN network in which the echo cancellation circuit will be used.

The present invention has been described in an illustrative manner. It is to be understood that the terminology which has been used is intended to be in the nature of words of description rather than of limitation.

Any modifications and variations of the present invention are possible in light of the above teachings. Therefore, within the scope of the appended claims, the present invention may be practiced otherwise than as specifically described.

What is claimed is:

1. An echo cancellation system for a controller area network (CAN) having at least one physical layer, said system including:
a flip flop circuit;
a first resistor capacitor tank circuit; and
a second resistor capacitor tank circuit.

2. The system of claim 1 wherein said flip flop circuit having a quad two input NOR gate.

3. The system of claim 1 wherein said flip flop circuit including a first diode and a second diode.

4. The system of claim 1 wherein said flip flop circuit having a transistor dependent delay that only delays a feedback signal of said flip flop circuit on falling edges.

5. The system of claim 4 wherein said falling edges include a dominate to recessive transition.

6. The system of claim 1 wherein said first tank circuit includes a first resistor, a second resistor and a capacitor.

7. The system of claim 1 wherein said second tank circuit includes a first resistor, a second resistor and a capacitor.

8. The system of claim 1 wherein said tank circuits are tuned to have a delay larger than a propagation delay of a CAN transceiver but less than a bit sample point of the CAN.

9. The system of claim 2 wherein the system operates in one of the following states:
a recessive state, a dominate state, a lockout state or an echo cancellation state.

10. The system of claim 9 wherein during said lockout state one of said NOR gates has a high output and an opposing said NOR gate is locked out and forced to stay low while one of said tank circuits is charged.

11. The system of claim 9 wherein during said echo cancellation state an output of one of said NOR gates becomes low and makes a transmit data input line of the opposing physical layer to become high, a diode will delay feedback to said opposing NOR gate by one of said tank circuits thus eliminating echo.

12. The system of claim 9 wherein during said recessive state outputs of said NOR gates are low and said tank circuits are discharged.

13. The system of claim 9 wherein during said dominate state one of said NOR gates becomes high and a transmit data input line of the opposing physical layer becomes low.

14. An echo cancellation system for use with a controller area network (CAN), said CAN including:
a first and a second physical layer;
a transceiver associated with each of said physical layer;
an echo cancellation circuit including:
a first NOR gate, a second NOR gate, a third NOR gate, a fourth NOR gate, a first RC tank circuit, a second RC tank circuit, a first diode and a second diode;
said first NOR gate in communication with a transition data input line of said transceiver of said first physical layer, said second NOR gate in communication with said first diode and said fourth NOR gate, said third NOR gate in communication with said first NOR gate and said second diode, said fourth NOR gate in communication with a transition data input line of said transceiver and said second physical layer, said first RC tank circuit in communication with said third NOR gate, said second RC tank circuit in communication with said second NOR gate.

15. A method of canceling echo between transceivers associated with a first and second physical layer of a controller area network (CAN), said method including the steps of:
tuning an echo cancellation circuit;
determining if a falling edge is occurring during a transition; and
delaying a feedback signal of said echo cancellation circuit a predetermined time.

16. The method of claim 15 wherein said falling edge is a dominate to recessive transition.

17. The method of claim 15 wherein said steps of delaying includes determining said length of a delay by a RC tank circuit, said delay is longer than a propagation delay of the transceivers but less than a bit sample point of the CAN.

18. The method of claim 15 wherein said echo cancellation circuit includes a quad NOR gate, a first RC tank circuit, a second RC tank circuit, a first diode, and a second diode.

19. The method of claim 17 wherein said delay is equal to or less than 40% of said bit sample.

20. The method of claim 15 further including the step of monitoring if the transceivers are in a recessive state, a dominate state, a lockout state, or an echo cancellation state.
